(19) United States
(12) Patent Application Publication
(10) Pub. No.: US 2009/0032829 A1
(43) Pub. Date: Feb. 5, 2009

(54) LED Light Source with Increased Thermal Conductivity

(76) Inventors: Tong Fatt Chew, Penang (MY); Siew It Pang, Penang (MY); Seong Choon Lim, Penang (MY)

Correspondence Address: Kathy Manke;Avago Technologies Limited, 4380 Ziegler Road, Fort Collins, CO, 80525, US

(21) Appl. No.: 11/830,535

(22) Filed: Jul. 30, 2007

(51) Int. Cl. H01L 33/00; H01L 21/00

(52) U.S. Cl. 257/98; 257/99; 438/26; 438/27; 257/E33.059; 257/E21.002

(57) ABSTRACT

A light source and method for making the same are disclosed. The light source includes a substrate, a plurality of dies and a transparent layer of encapsulant. The substrate includes an insulating layer having top and bottom surfaces, the top surface having a first metal patterned layer thereon, and the bottom surface having a second metal patterned layer thereon. The first metal patterned layer has a plurality of die mounting areas thereon, and the second metal patterned layer includes a first contact layer that underlies the die mounting area, the die mounting area and the first contact layer being connected by metal lined vias at each of the die mounting areas. The transparent encapsulant covers the plurality of dies and is bonded to the first metal patterned layer and the top surface of the insulating layer.

### BACKGROUND OF THE INVENTION

Illumination sources are required for many applications, including displays for a wide variety of computers and consumer devices such as TVs. Illumination sources based on fluorescent lights are particularly attractive because of their high light output per watt-hour of power consumed. However, such sources require high driving voltages, and this makes them less attractive for battery-operated devices. In addition, many applications require light sources that are essentially point sources. Fluorescent sources cannot be used in most of these applications, since fluorescent sources are inherently extended sources.

As a result, there has been considerable interest in utilizing light sources based on LEDs in such applications. LEDs have better electrical efficiency than incandescent light sources and longer lifetimes than both incandescent and fluorescent light sources. In addition, the driving voltages needed are compatible with the battery power available on most portable devices. LEDs are inherently point light sources, and hence, can be utilized in arrangements in which a lens is used for optical processing of the light. Finally, continued advancements in the efficiencies of LEDs hold the promise of providing a light source with significantly higher efficiencies than fluorescent light sources. Unfortunately, LEDs suffer from a number of problems.

In particular, the amount of light that can be produced by a single LED is small compared to that provided by an incandescent light source. The maximum power that can be dissipated in an LED is of the order of 5 watts. This limitation is imposed by the need to maintain the junction temperature of the LED at temperatures that are considerably less than those utilized in incandescent lamps and by the limitations of the packaging systems currently used for LEDs. The efficiency of the typical LED decreases with increasing junction temperature, and hence, the LEDs must be operated at junction temperatures that are less than about 125° C. To maintain the junction temperature below this temperature, the die containing the LED is typically mounted on a heat sink that dissipates the heat by conducting the heat to a large surface area such as the core of a printed circuit board.

Second, because of the limited light output of a single LED, many applications require multiple LEDs with the number of LEDs varying from light source to light source. Providing a separate packaging scheme for each application substantially increases the cost of the light sources. However, in lighting applications, packaging cost must be kept to a minimum.

Third, LED packages include a number of components that have substantially different thermal coefficients of expansion. A typical prior art package has a heat conducting substrate on which the die is mounted, a reflector made of a different material than that used to redirect light leaving the sides of the die, and an encapsulant material that protects the die and provides improved light extraction from the die. Typically, the reflector is mounted on the heat conducting substrate before the LED is attached to the heat conducting substrate. The die attachment process often involves high temperatures that stress the bond between the reflector and the heat conducting substrate. After the LED has been encapsulated, the LED is often subjected to additional high temperature cycling during the attachment of the LED to a printed circuit board or the like in the final product. This processing further stresses the components.

Finally, the need to increase the power output per LED has resulted in light sources that operate at higher temperatures than previous light sources. In such light sources, the LED package is thermally stressed each time the light is turned on.

### SUMMARY OF THE INVENTION

The present invention includes a light source and method for making the same. The light source includes a substrate, a plurality of dies and a transparent layer of encapsulant. The substrate includes an insulating layer having top and bottom surfaces, the top surface having a first metal patterned layer thereon, and the bottom surface having a second metal patterned layer thereon. The first metal patterned layer has a first portion that includes a plurality of die mounting areas thereon, and the second metal patterned layer includes a first contact layer that underlies the die mounting area, the die mounting area and the first contact layer being connected by metal lined vias at each of the die mounting areas. Each die includes a solid state light emitter mounted on a corresponding one of the die mounting areas and connected electrically thereto. The transparent encapsulant covers the plurality of dies and is bonded to the first metal patterned layer and the top surface of the insulating layer. In one aspect of the invention, each of the dies can be mounted in a reflector that redirects light leaving a side surface of the die. In another aspect of the invention, the light emitters are LEDs that are arranged in a linear array and the encapsulant includes a layer of material having a cylindrical outer surface with an axis parallel to the linear array. In another aspect of the invention, a portion of the substrate is exposed, the exposed portion includes a plurality of terminals for connecting the light source to a power source.

### BRIEF DESCRIPTION OF THE DRAWINGS

FIG. 1 is a cross-sectional view of a prior art light source 20 based on an LED.

FIG. 2 is a top view of carrier 30.

FIG. 3 is a bottom view of carrier 30.

FIG. 4 is a cross-sectional view of carrier 30 through line 4-4 shown in FIG. 2.

FIG. 5 is a cross-sectional view of carrier 30 through line 5-5 shown in FIG. 2.

FIG. 6 is a perspective view of a portion of a light source prior to the encapsulation of the die according to one embodiment of the present invention.

FIG. 7 illustrates a linear light source 70 that is formed from a plurality of dies that are arranged in a linear array on a common substrate.

FIG. 8 illustrates a light source 80 that is constructed from a single LED that is mounted on a substrate having a single mounting pad.

FIG. 9 is a perspective view of a linear light source 90 constructed from two linear light source modules.

FIG. 10 is a cross-sectional view of a linear light source connected to a light pipe according to the present invention.

FIGS. 11 and 12 illustrate one embodiment of a fabrication scheme for light sources according to the present invention.

### DETAILED DESCRIPTION OF THE PREFERRED EMBODIMENTS OF THE INVENTION

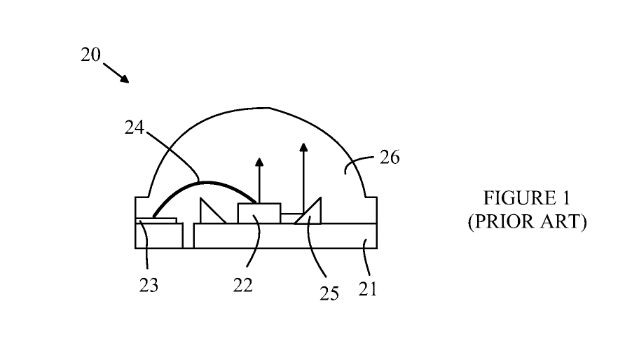

The manner in which the present invention provides its advantages can be more easily understood with reference to FIG. 1, which is a cross-sectional view of a prior art light source based on an LED. Light source 20 includes a base 21 on which a die 22 containing the LED is mounted. Die 22 is powered by a first contact that is on the bottom surface of the die and a second contact that is on the top surface of the die. The die is bonded to base 21 by an electrically conducting adhesive such that base 21 also provides the electrical connection to the first contact. Base 21 also provides a heat path for removing the heat generated in die 22. Base 21 includes a section 23 that is electrically isolated from the bottom surface of die 22 and that provides the second contact needed to power the LED. This second connection is made by a wire bond 24.

Light source 20 also includes a cup 25 with reflective sidewalls that redirect light leaving the side surfaces of die 22. The various components are encapsulated in an encapsulant layer 26 that protects die 22. Layer 26 also improves the extraction of light from die 22 by providing a medium having an index of refraction that is greater than that of air, and hence, reduces the mismatch between the index of refraction of the materials from which die 22 is constructed and the surrounding medium. The curved upper surface of layer 26 reduces the amount of light that is trapped within layer 26 by the same index of refraction mismatch. In addition, the curved surface can provide optical processing of the light from die 22. In some light sources, an additional lens is mounted over layer 26.

As noted above, the various components have significantly different thermal coefficients of expansion and are typically constructed from rigid materials. For example, base 21 is typically a rigid member that includes a lead frame, a printed circuit board, or a ceramic substrate. Reflector 25 can be a plastic molded part or a metal reflective cup. The encapsulant is often an epoxy material.

The difference in the thermal coefficients of expansion between the components can lead to device failures if the light source is thermally cycled between sufficiently different temperatures. Such thermal cycling occurs during the fabrication of the light source, the mounting of the light source in the final product, and later when the light source is used. As the power dissipation of the LED light sources is increased to compete with conventional light sources, this latter source of thermal cycling becomes significant and can lead to device failure in the field.

Many lighting applications require light sources that include a number of LEDs arranged in a geometric pattern that is particular to the light source in question. For example, a spot light typically requires an LED that is mounted with a collimating lens, and hence, the LED must be essentially a point source at the focal point of a circularly symmetric lens. A light source for use in illuminating a flat panel display typically is configured as a linear light source and requires a number of LEDs arranged in a linear array under a cylindrical lens. Hence, a fabrication system that can generate different configurations of light sources with minimal changes would be advantageous.

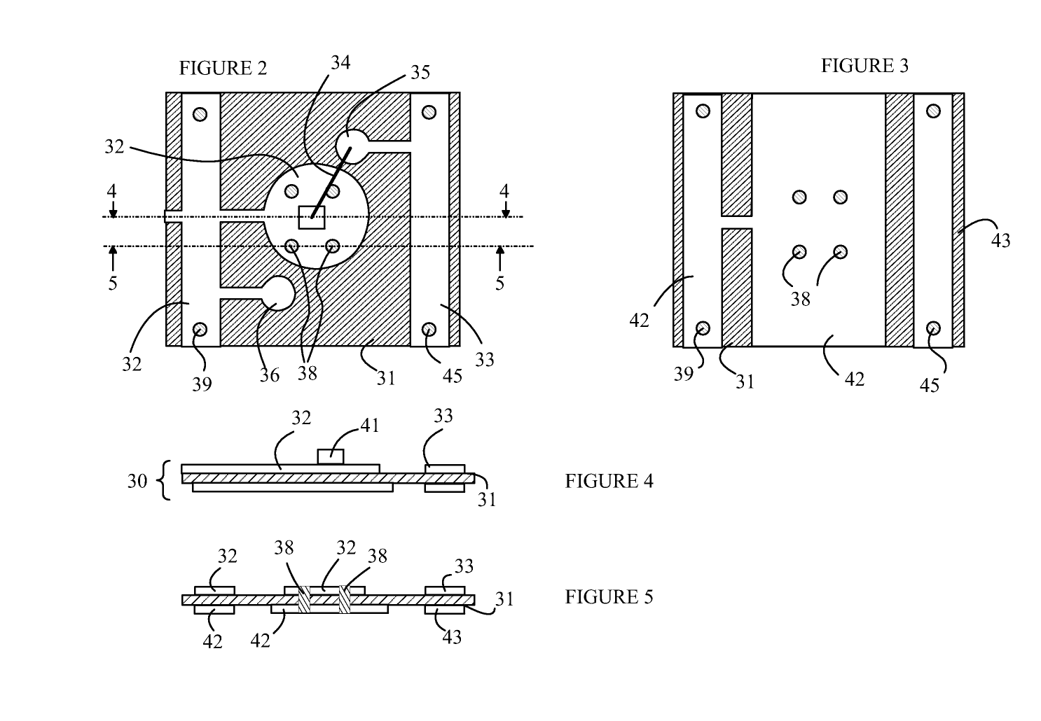

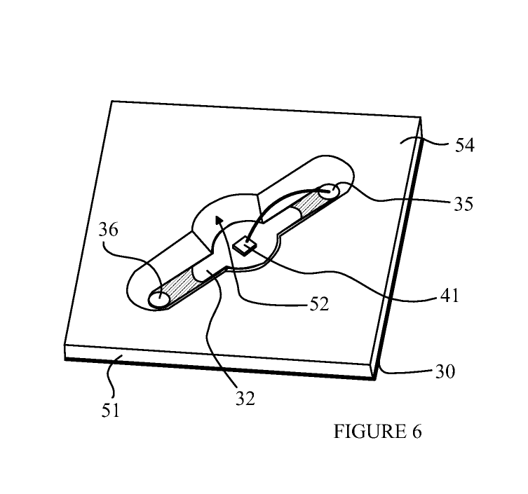

A light source according to the present invention utilizes a flexible circuit carrier as the base member. Refer now to FIGS. 2-5, which illustrate a section of such a carrier with a die mounted thereon. FIG. 2 is a top view of carrier 30; FIG. 3 is a bottom view of carrier 30, and FIGS. 4 and 5 are cross-sectional views through lines 4-4 and 5-5, respectively. Circuit carrier 30 includes two patterned metal layers that are disposed on opposite sides of a flexible insulating substrate 31. The top layer is patterned to provide first and second top electrodes 32 and 33. A die 41 containing an LED is bonded to electrode 32. Die 41 includes first and second contacts that are used to power the LED. In this exemplary embodiment, the first contact is on the bottom surface of die 41 and second contact is on the top surface of die 41. The die can be bonded to the die mounting area using an eutectic die attachment material as well as metal-filled polymeric attachment materials.

The second contact is connected to electrode 33 by a wire bond 34 that is bonded to pad 35 on electrode 33. In this embodiment, die 41 is bonded to electrode 32 by a conductive adhesive. The adhesive bond provides both electrical connection to electrode 32 and thermal connection between die 41 and electrode 32. In embodiments in which both the first and second contacts on the die are on the top surface, a second pad shown at 36 is used to make the connection between electrode 32 and the second contact. In such embodiments, the bond between die 41 and electrode 32 can be electrically insulating; however, the bond must still have a sufficiently low heat resistance to allow heat generated in the die to be transferred to electrode 32 without subjecting the die to excessive temperatures.

Refer now to FIGS. 3 and 5. The bottom surface of layer 31 has a metal layer that is patterned to provide electrodes 42 and 43. Electrode 43 is connected to electrode 33 by conducting vias such as the via shown at 45. Electrode 42 is connected to electrode 32 by conducting vias such as the vias shown at 38 and 39. The vias shown at 38 are sized to conduct heat from electrode 32 through layer 31 to electrode 42. These vias have a thermal resistance that is sufficiently low to assure that the temperature difference between electrodes 32 and 42 is minimized when the die is powered at the maximum design power for the light source. This assures that the vias will not present a thermal resistance that limits the heat removal from die 41. As will be explained in more detail below, electrode 42 is exposed on the bottom surface of the completed light source and can be thermally connected to a matching electrode on the surface of a printed circuit board.

In one embodiment, substrate 31 utilizes a flexible circuit technology in which 31 is constructed from an organic material such as polyamide, siloxane, polyester, cyanate ester, bismaleimide or glass fiber. Films and laminates of polyamide are available commercially from Dupont and utilize substrates called Kapton™ made from polyimide and, in some cases, a plurality of layers are laminated with an adhesive. This type of circuit carrier is significantly less expensive than silicon substrate-based circuitry and can be provided with relatively thin substrates. However, embodiments in which layer 31 is constructed from silicone can also be constructed. In one embodiment, a Pyralux AP laminate from Dupont that has a 2 mils thick Kapton™ layer and copper layers on the top and bottom surfaces is utilized. The thickness of the layers and the dimensions of the electrodes are chosen to provide sufficient heat transfer from die 41 to the printed circuit board without significantly increasing the temperature at which die 41 operates. In one embodiment, the insulating substrate 31 is between 10 μm and 100 μm, and the metal layers are between 10 μm and 150 μm. The metal layers can be constructed from copper, nickel, gold, silver, palladium, rhodium, tin, aluminum or alloys thereof.

In some embodiments, a reflector is required around die 41. Such a reflector can be provided by bonding a separate layer to circuit carrier 30. Refer now to FIG. 6, which is a perspective view of a portion of a light source according to one embodiment of the present invention prior to the encapsulation of the die. The reflector is created by bonding a layer 51 of insulating material to circuit carrier 30. The layer has a cut-out with reflective walls 52 that reflect light leaving the side of die 41 such that the light exits within a cone of angles that are approximately perpendicular to surface 54 of layer 51. If the light source requires only a diffused reflection finish on the reflective walls, layer 51 can be constructed from a white material such as silicone having particles of TiO₂. If a more specular reflection finish is required, layer 51 can be coated with a metallic film.

Layer 51 preferably has a thermal coefficient of expansion that is substantially the same as that of layer 31 in carrier 30. Layer 51 can be rigid or flexible depending on the particular application. Flexible layers have the advantage of being capable of deforming in response to a difference in thermal coefficient of expansion. In this regard, it should be noted that the metal layers in carrier 30 will, in general, have different thermal coefficients of expansion than layer 31 or layer 51. Hence, even if layer 31 and layer 51 have substantially the same coefficients of thermal expansion, flexible layers will still have advantages in reducing stress during temperature cycling.

In one embodiment, layer 51 is bonded to carrier 30 prior to the attachment of die 41. Hence, the opening in layer 51 must be sufficient to accommodate the insertion and bonding of both die 41 and the wire bond that connects die 41 to pad 35 on electrode 33. It is advantageous to provide one substrate and reflector layer that can be used with dies having the contacts on the top surface of the die as well as dies having one contact on the bottom surface of the die and one contact on the top surface of the die. Hence, the opening in layer 51 is sized and positioned such that pad 36 can also be accessed during the attachment and connection of the die.

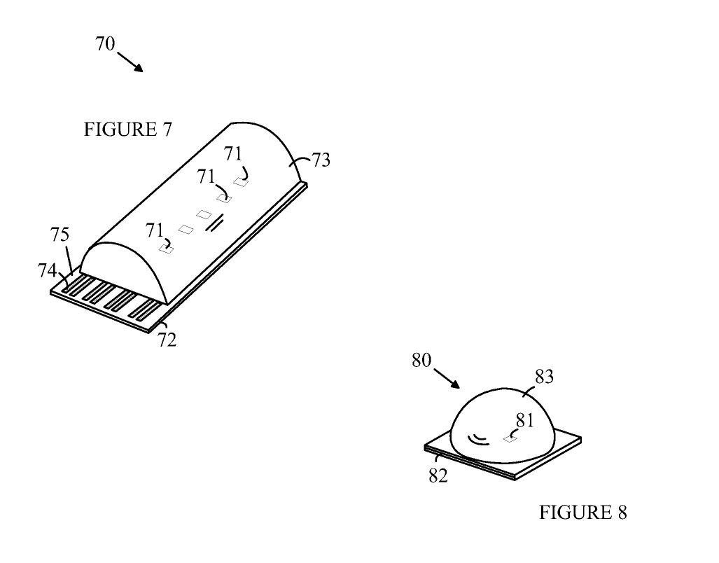

After the die has been attached to carrier 30 and electrically connected to the electrodes on substrate 31 the substrate and die are encapsulated in a transparent medium. The shape of the encapsulation layer depends on the particular light source design. Refer now to FIGS. 7 and 8, which are perspective views of two exemplary encapsulation configurations. FIG. 7 illustrates a linear light source 70 that is formed from a plurality of dies shown at 71 that are arranged in a linear array on a common substrate 72. The dies are encapsulated in a transparent layer of material shown at 73. The transparent material can include a number of additives such as phosphors and diffusants that convert a portion of the light from the LEDs to light of a different spectrum and diffuse the light such that the light source appears to be a uniformly illuminated cylindrical source having the shape of encapsulation layer 73.

The individual LEDs can be of the same color or of different colors. In the case of a light source based on LEDs of different colors, the dies are arranged in an alternating fashion in repeating groups. For example, groups of three LEDs that provide red, blue, and green light, respectively, can be arranged in the linear array. In general, the connections to the LEDs in a particular module such as light source 70 are separated so that the individual LEDs can be driven separately. The external connections can be through a separate connector 75 consisting of traces 74 that are part of substrate 72. The individual LEDs can also be accessed by the exposed portions of the bottom layer of the substrate.

FIG. 8 illustrates a light source 80 that is constructed from a single LED 81 that is mounted on a substrate 82 having a single mounting pad. The LED and substrate are encapsulated in a layer of encapsulant 83 having a spherical surface. The outer surface can be shaped to provide a lens that collimates or otherwise processes the output light. In the absence of additives that diffuse the light, light source 80 is a point source with a lens. If layer 83 includes additives such as those described above, light source 80 appears to be a small, extended source having the dimensions of the encapsulant layer.

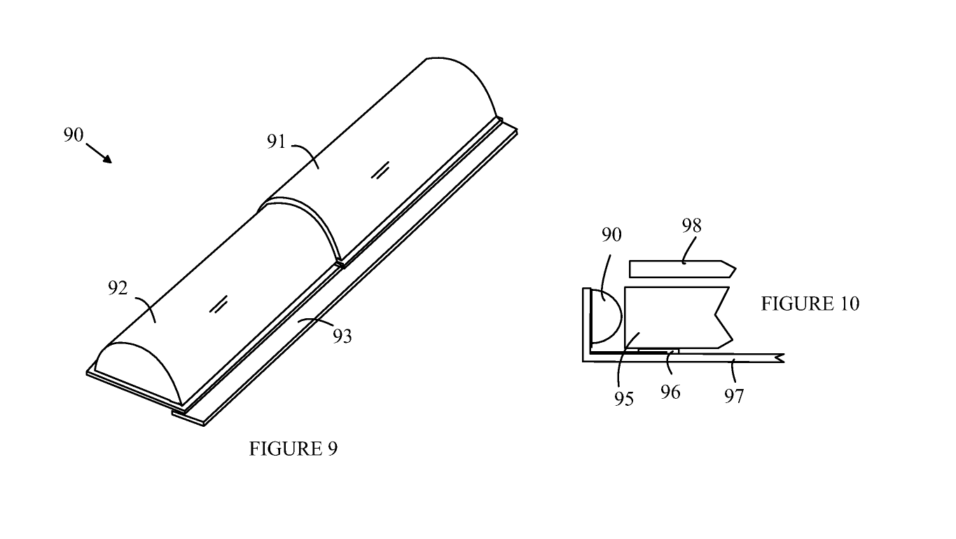

A number of light sources such as light source 70 shown in FIG. 7 can be combined to provide an extended linear light source having a configuration that is adapted for illuminating the edge of a planar light pipe of the type utilized for backlit displays. Refer now to FIG. 9, which is a perspective view of a linear light source 90 constructed from two linear light source modules 91 and 92 of the type discussed above with respect to FIG. 7, but without the end connector. The light source modules are bonded to a common flex connector 93 that includes traces for powering the individual LEDs within each light source module.

Refer now to FIG. 10, which is a cross-sectional view of a linear light source according to the present invention connected to a light pipe. Light source 90 is positioned along the edge of light pipe 95. The traces on flex connector 93 are connected to mating traces in a connector 96 that is mounted on a structure connected to the light pipe. An optional metal casing 97 can be attached to light source 90 and used to transfer heat to a heat-dissipating surface. The light source can be used to illuminate an LCD panel 98 or a transparency that is viewed by a user.

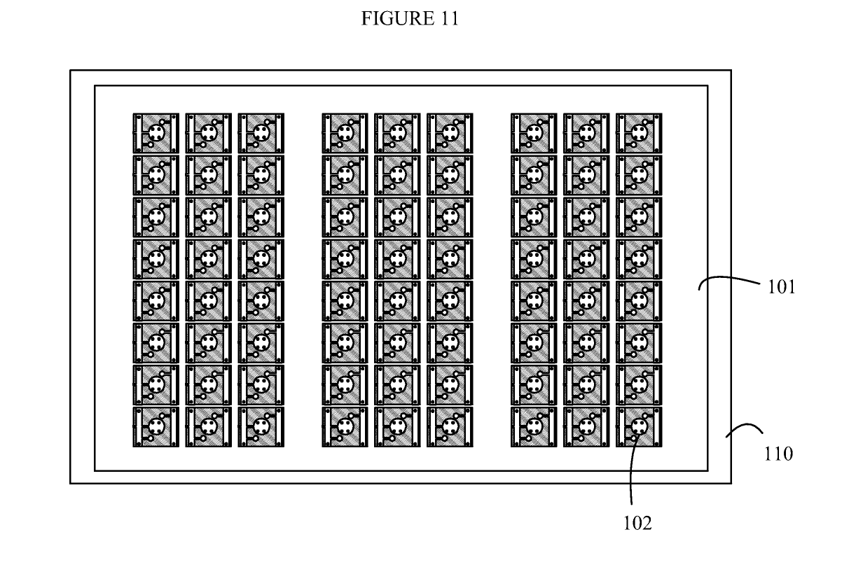

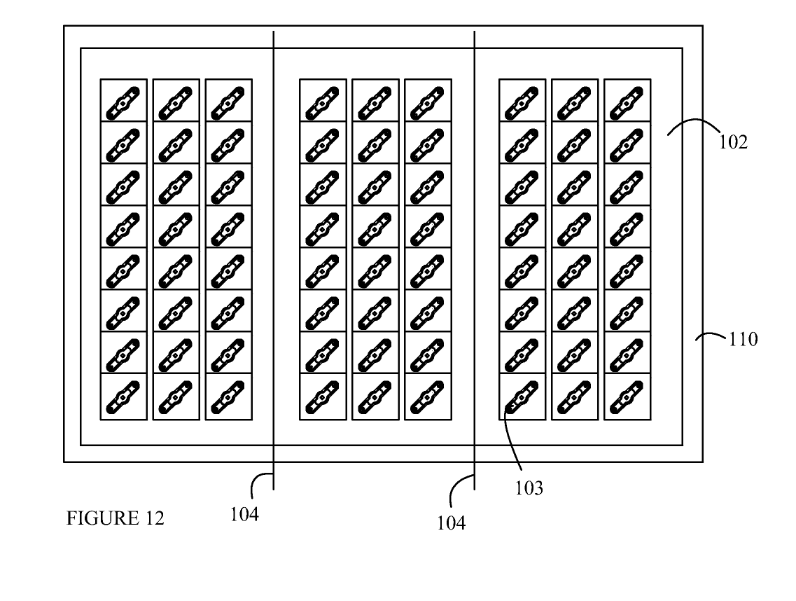

Refer now to FIGS. 11 and 12, which illustrate one embodiment of a fabrication scheme for light sources according to the present invention. Referring to FIG. 11, the process begins with a sheet of substrate 101 such as substrate 31 discussed above. The substrate sheet is attached to a rigid carrier 110. The metal layers on the top and bottom surfaces are patterned to provide the mounting pads and electrodes for the die as shown at 102. The flexible sheet is mounted on a rigid carrier during the fabrication process. Referring to FIG. 12, a layer of material having the reflector cups 103 cutout therefrom is bonded to the surface of substrate 101. The dies are then bonded to the pads and electrically connected as described above. The bonded sheets are then placed in a mold and the encapsulating material molded over the reflector cups. The individual light sources are then singulated by cutting the molded sheet.

The shape of the encapsulation layer and the number of dies in each light source depend on the particular product in which the light sources are to be incorporated. In the embodiment shown in FIG. 12, the light sources are grouped into groups of three in the horizontal direction. Hence, a light source having three different color LEDs can be obtained by cutting the encapsulated sheet along the lines shown at 104 and between each row of light sources in the horizontal direction.

Various modifications to the present invention will become apparent to those skilled in the art from the foregoing description and accompanying drawings. Accordingly, the present invention is to be limited solely by the scope of the following claims.

What is claimed is:

1. A light source comprising:
a substrate comprising an insulating layer having top and bottom surfaces, said top surface having a first metal patterned layer thereon and said bottom surface having a second metal patterned layer thereon, said first metal patterned layer having a first portion comprising a plurality of die mounting areas thereon and said second metal patterned layer comprises a first contact layer that underlies said die mounting area, said die mounting area and said first contact layer being connected by metal lined vias at each of said die mounting areas;
a plurality of dies, each die comprising a solid state light emitter mounted on a corresponding one of said die mounting areas and connected electrically thereto; and
a transparent encapsulant covering said plurality of dies and bonded to said first metal patterned layer and said top surface of said insulating layer.

2. The light source of claim 1 wherein each of said dies is mounted in a reflector that redirects light leaving a side surface of said die.

3. The light source of claim 1 wherein said insulating layer has a thickness between 10 μm and 100 μm.

4. The light source of claim 1 wherein said metal patterned layers have a thickness between 10 μm and 150 μm.

5. The light source of claim 1 wherein said metal patterned layers comprise a metal chosen from the group consisting of copper, nickel, gold, silver, palladium, rhodium, tin, and aluminum or alloys of said metals.

6. The light source of claim 1 wherein said insulating layer comprises a material chosen from the group consisting of polyimide, siloxane, polyester, cyanate ester, bismaleimide and glass fiber.

7. The light source of claim 1 wherein said encapsulant comprises silicone or epoxy.

8. The light source of claim 1 wherein said solid state light emitting element comprises an LED.

9. The light source of claim 8 wherein said LEDs are arranged in a linear array and said encapsulant comprises a layer of material having a cylindrical outer surface with an axis parallel to said linear array.

10. The light source of claim 9 wherein a portion of said substrate is exposed, said exposed portion comprising a plurality of terminals for connecting said light source to a power source.

11. The light source of claim 10 wherein said exposed portion comprises a portion of said substrate at an end of said linear array.

12. A light source comprising a plurality of light generating modules bonded to a flexible connector, each module comprising:
a substrate comprising an insulating layer having top and bottom surfaces, said top surface having a first metal patterned layer thereon and said bottom surface having a second metal patterned layer thereon, said first metal patterned layer having a first portion comprising a plurality of die mounting areas thereon and said second metal patterned layer comprises a first contact layer that underlies said die mounting area, said die mounting area and said first contact layer being connected by metal lined vias at each of said die mounting areas;
a plurality of dies, each die comprising a solid state light emitter mounted on a corresponding one of said die mounting areas and connected electrically thereto; and
a transparent encapsulant covering said plurality of dies and bonded to said first metal patterned layer and said top surface of said insulating layer,
said flexible connector comprising an insulating layer having a plurality of metallic traces thereon, said traces providing connections for powering said solid state light emitters.

13. The light source of claim 12 wherein said dies in each of said modules are arranged in a linear array, said modules being connected to said flexible connector such that said linear arrays are aligned with one another to provide a linear light source that is longer than each of said modules.

14. The light source of claim 13 further comprising a light pipe comprising a layer of transparent material having a top surface, a bottom surface and a side surface, said linear array being positioned to emit light into said side surface.

15. The light source of claim 14 wherein said flexible connector comprises a plurality of electrical traces that mate with a power connector in said light source.

16. The light source of claim 15 wherein said flexible connector has a section bent such that said section is parallel to said bottom surface of said layer of transparent material.

17. The light source of claim 14 further comprising an LCD display overlying said top surface of said layer of transparent material.

18. A method for fabricating a light source comprising:
mounting a substrate on a rigid carrier, said substrate comprising an insulating layer having top and bottom surfaces, said top surface having a first metal patterned layer thereon and said bottom surface having a second metal patterned layer thereon, said first metal patterned layer having a first portion comprising a plurality of die mounting areas thereon and said second metal patterned layer comprises a first contact layer that underlies said die mounting area, said die mounting area and said first contact layer being connected by metal lined vias at each of said die mounting areas;
bonding said dies to said first metal patterned layer and connecting said dies electrically to electrodes formed in said first metal patterned layer;
molding an encapsulant layer over said substrate and rigid carrier; and
dividing said substrate and rigid carrier so as to singulate a plurality of light sources.

19. The method of claim 18 further comprising attaching a layer of material having reflectors cut therein to said substrate on said patterned metal layer and said top surface of said insulating layer prior to bonding said dies.

20. The method of claim 18 wherein said encapsulant is molded to provide a cylindrical lens overlying a plurality of said dies.
